(19) United States
(12) Patent Application Publication
(10) Pub. No.: US 2025/0072084 A1
(43) Pub. Date: Feb. 27, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Takuo KIKUCHI, Kamakura (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/604,329

(22) Filed: Mar. 13, 2024

(30) Foreign Application Priority Data
Aug. 24, 2023 (JP) 2023-136455

(51) Int. Cl. H01L 29/40; H01L 29/78

(52) U.S. Cl. CPC H01L 29/407; H01L 29/7813

(57) ABSTRACT

A semiconductor device includes first to fourth electrodes, first to third semiconductor regions, and first and second insulating parts. The first insulating part is located between the second semiconductor region and the third electrode. The fourth electrode is arranged with the first and second semiconductor regions. The second insulating part is located between the first semiconductor region and the fourth electrode and between the second semiconductor region and the fourth electrode. the second insulating part includes first and second insulating regions. The first insulating region surrounds the fourth electrode and contacts the fourth electrode. The second insulating region surrounds the first insulating region and contacts the first insulating region. A dielectric constant of the second insulating region is less than a dielectric constant of the first insulating region.

### CROSS-REFERENCE TO RELATED APPLICATIONS

This application is based upon and claims the benefit of priority from Japanese Patent Application No. 2023-136455, filed on Aug. 24, 2023; the entire contents of which are incorporated herein by reference.

### FIELD

Embodiments described herein relate generally to a semiconductor device.

### BACKGROUND

A semiconductor device that includes a dot-shaped field plate electrode (hereinbelow, called “FP electrode”) is known to enable increased breakdown voltage and reduced on-resistance. It is desirable to suppress electric field concentration at the FP electrode of such a semiconductor device.

### BRIEF DESCRIPTION OF THE DRAWINGS

FIG. 1 is a plan view illustrating the semiconductor device according to the embodiment;

FIG. 2 is a cross-sectional view illustrating the semiconductor device according to the embodiment; and

FIG. 3 is a graph illustrating characteristics of semiconductor devices of reference examples.

### DETAILED DESCRIPTION

A semiconductor device according to an embodiment includes a first electrode, a first semiconductor region of a first conductivity type, a second semiconductor region of a second conductivity type, a third semiconductor region of the first conductivity type, a second electrode, a third electrode, a first insulating part, a fourth electrode, and a second insulating part. The first semiconductor region is located on the first electrode. The second semiconductor region is located on the first semiconductor region. The third semiconductor region is selectively provided on the second semiconductor region. The second electrode is located on the third semiconductor region. The second electrode is electrically connected with the third semiconductor region. The third electrode is arranged with the second semiconductor region in a second direction and a third direction. The second direction is perpendicular to a first direction; and the first direction is from the first semiconductor region toward the second semiconductor region. The third direction is perpendicular to the first direction and crosses the second direction. The first insulating part is located between the second semiconductor region and the third electrode in the second and third directions. The fourth electrode is arranged with the first and second semiconductor regions in the second and third directions. The second insulating part is located between the first semiconductor region and the fourth electrode and between the second semiconductor region and the fourth electrode in the second and third directions. The second insulating part includes a first insulating region and a second insulating region. The first insulating region surrounds the fourth electrode and contacts the fourth electrode. The second insulating region surrounds the first insulating region and contacts the first insulating region. The dielectric constant of the first insulating region is less than the dielectric constant of the second insulating region.

Exemplary embodiments will now be described with reference to the drawings. The drawings are schematic or conceptual; and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions. Furthermore, in the specification of the application and the drawings, components similar to those described in regard to a drawing thereinabove are marked with like reference numerals; and a detailed description is omitted as appropriate.

For easier understanding of the following description, the arrangements and configurations of the portions are described using an XYZ orthogonal coordinate system. An X-axis, a Y-axis, and a Z-axis are orthogonal to each other. The direction in which the X-axis extends is taken as an “X-direction”; the direction in which the Y-axis extends is taken as a “Y-direction”; and the direction in which the Z-axis extends is taken as a “Z-direction”. Although the direction of the arrow in the Z-direction is taken as up and the opposite direction is taken as down for easier understanding of the description, these directions are independent of the direction of gravity. Viewing from above is called “plan view”.

Hereinbelow, the notations of + and − indicate relative levels of the impurity concentrations of each conductivity type. Specifically, a notation marked with “+” indicates a higher impurity concentration than a notation not marked with either “+” or “−”. A notation marked with “−” indicates a lower impurity concentration than a notation not marked with either “+” or “−”. Here, when both an impurity that forms donors and an impurity that forms acceptors are included in each region, the “impurity concentration” means the net impurity concentration after the impurities cancel.

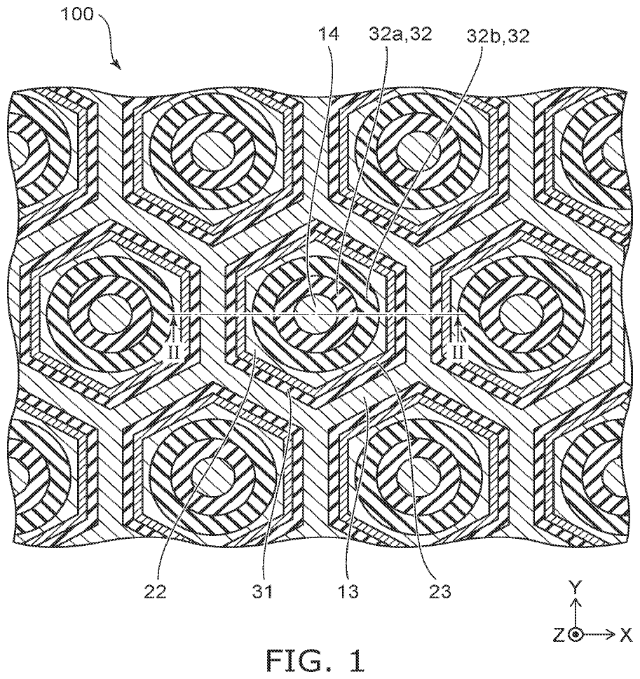

FIG. 1 is a plan view illustrating the semiconductor device according to the embodiment.

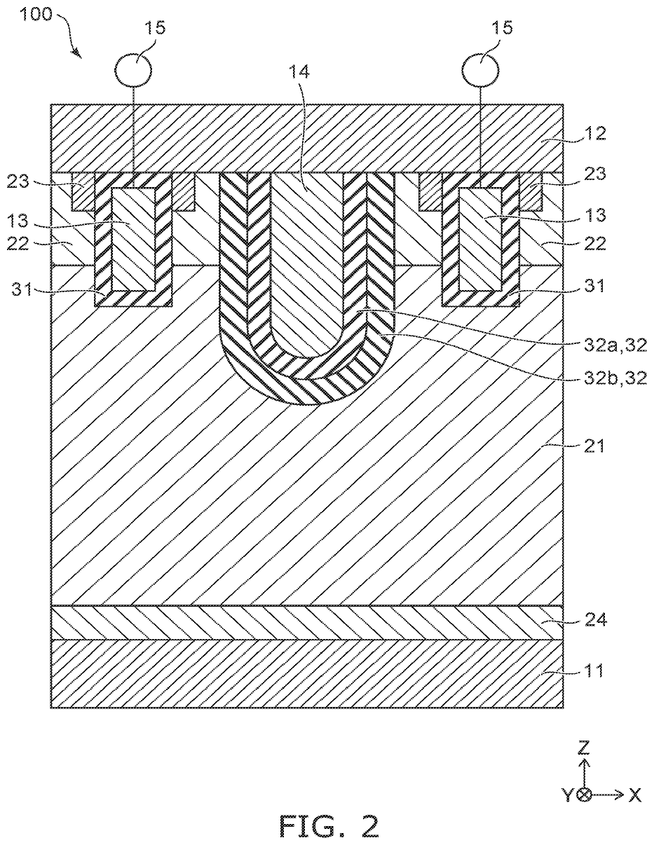

FIG. 2 is a cross-sectional view illustrating the semiconductor device according to the embodiment.

FIG. 2 is a cross-sectional view along line II-II shown in FIG. 1.

As illustrated in FIGS. 1 and 2, the semiconductor device 100 according to the embodiment is, for example, a vertical MOSFET (Metal-Oxide-Semiconductor Field-Effect Transistor). The semiconductor device 100 is a MOSFET that includes dot-shaped FP electrodes and a trench configuration gate electrode between the FP electrodes.

The semiconductor device 100 includes a drain electrode 11 (a first electrode), a source electrode 12 (a second electrode), a gate electrode 13 (a third electrode), a FP electrode 14 (a fourth electrode), a gate pad 15, an n⁻-type drift region 21 (a first semiconductor region), a p-type base region 22 (a second semiconductor region), an n⁺-type source region 23 (a third semiconductor region), an n⁺-type drain region 24, a gate insulating part 31 (a first insulating part), and a FP insulating part 32 (a second insulating part). In the example, the first conductivity type is an n-type; and the second conductivity type is a p-type.

Hereinbelow, the direction from the first electrode 11 toward the second electrode 12 is taken as a first direction. A direction perpendicular to the first direction is taken as a second direction. A direction that is perpendicular to the first direction and crosses the second direction is taken as a third direction. The first direction is, for example, a Z-direction. The second direction is, for example, an X-direction. The third direction is, for example, a Y-direction.

The drain electrode 11 is located at the lower portion of the semiconductor device 100. The n⁻-type drift region 21 is located on the drain electrode 11 with the n⁺-type drain region 24 interposed. The n⁻-type drift region 21 is electrically connected with the drain electrode 11 via the n⁺-type drain region 24. The p-type base region 22 is located on the n⁻-type drift region 21. The n⁺-type source region 23 is selectively provided on the p-type base region 22. In the example, the n⁺-type source region 23 is located on a portion of the p-type base region 22; and the n⁺-type source region 23 is not located on other portions of the p-type base region 22. The n⁺-type source region 23 is arranged with the p-type base region 22 in the X-direction and Y-direction. The source electrode 12 is located on the p-type base region 22 and the n⁺-type source region 23. The source electrode 12 is electrically connected with the p-type base region 22 and the n⁺-type source region 23. FIG. 1 is a plan view in which the source electrode 12 is not illustrated.

The gate electrode 13 is arranged with the p-type base region 22 in the X-direction and Y-direction. In the example, a portion of the gate electrode 13 is arranged with a portion of the n⁻-type drift region 21 in the X-direction and Y-direction. In the example, a portion of the gate electrode 13 is arranged with a portion of the n⁺-type source region 23 in the X-direction and Y-direction.

The gate insulating part 31 is located between the gate electrode 13 and the p-type base region 22 in the X-direction and Y-direction. In the example, a portion of the gate insulating part 31 is located between the gate electrode 13 and the n⁻-type drift region 21 in the X-direction and Y-direction. In the example, a portion of the gate insulating part 31 is located between the gate electrode 13 and the n⁺-type source region 23 in the X-direction and Y-direction. In the example, a portion of the gate insulating part 31 is located between the gate electrode 13 and the n⁻-type drift region 21 in the Z-direction. In the example, a portion of the gate insulating part 31 is located between the gate electrode 13 and the source electrode 12 in the Z-direction. Thus, the gate electrode 13 is surrounded with the gate insulating part 31. The gate electrode 13 is located inside the gate insulating part 31.

The gate electrode 13 is electrically connected with the gate pad 15. The gate pad 15 is electrically isolated from the source electrode 12. The gate electrode 13 may be electrically connected with the gate pad 15 via a not-illustrated gate wiring layer.

The FP electrode 14 is arranged with the n⁻-type drift region 21 and the p-type base region 22 in the X-direction and Y-direction. In the example, a portion of the FP electrode 14 is arranged with a portion of the n⁺-type source region 23 in the X-direction and Y-direction.

The FP insulating part 32 is located between the FP electrode 14 and the n⁻-type drift region 21 and between the FP electrode 14 and the p-type base region 22 in the X-direction and Y-direction. In the example, a portion of the FP insulating part 32 is located between the FP electrode 14 and the n⁻-type drift region 21 in the Z-direction. Thus, the FP electrode 14 is surrounded with the FP insulating part 32. The FP electrode 14 is located inside the FP insulating part 32. The FP electrode 14 is electrically connected with the source electrode 12.

The FP insulating part 32 includes a first insulating region 32a and a second insulating region 32b. The first insulating region 32a surrounds the FP electrode 14 in the X-Y plane. The first insulating region 32a contacts the FP electrode 14. The second insulating region 32b surrounds the first insulating region 32a in the X-Y plane. The second insulating region 32b contacts the first insulating region 32a. The first insulating region 32a is located between the FP electrode 14 and the second insulating region 32b. The first insulating region 32a is located inside the second insulating region 32b; and the FP electrode 14 is located inside the first insulating region 32a.

The dielectric constant of the second insulating region 32b is less than the dielectric constant of the first insulating region 32a. The ratio of the dielectric constant of the second insulating region 32b to the dielectric constant of the first insulating region 32a is, for example, not less than ½ and not more than ⅘. For example, the dielectric constant of the first insulating region 32a is constant inside the first insulating region 32a. For example, the dielectric constant of the second insulating region 32b is constant inside the second insulating region 32b. That is, for example, the dielectric constant of the FP insulating part 32 discontinuously decreases from the FP electrode 14 toward the n⁻-type drift region 21 or p-type base region 22.

For example, the thickness of the first insulating region 32a and the thickness of the second insulating region 32b each are greater than the thickness of a native oxide film (e.g., about 1 nm). The thickness of the second insulating region 32b is, for example, not less than 0.1 times and not more than 10 times the thickness of the first insulating region 32a.

For example, the thickness of the first insulating region 32a is represented by the average value of the X-direction length of the first insulating region 32a, the Y-direction length of the first insulating region 32a, and the Z-direction length of the first insulating region 32a. The X-direction length of the first insulating region 32a, the Y-direction length of the first insulating region 32a, and the Z-direction length of the first insulating region 32a are, for example, equal. That is, the thickness of the first insulating region 32a is, for example, uniform.

For example, the thickness of the second insulating region 32b is represented by the average value of the X-direction length of the second insulating region 32b, the Y-direction length of the second insulating region 32b, and the Z-direction length of the second insulating region 32b. The X-direction length of the second insulating region 32b, the Y-direction length of the second insulating region 32b, and the Z-direction length of the second insulating region 32b are, for example, equal. That is, the thickness of the second insulating region 32b is, for example, uniform.

The FP insulating part 32 may further include another insulating region that surrounds the second insulating region 32b and contacts the second insulating region 32b. In such a case, it is favorable for the dielectric constant of the other insulating region to be less than the dielectric constant of the second insulating region 32b. The other insulating region may include multiple layers having different dielectric constants. In such a case, it is favorable for the dielectric constants of the multiple layers to decrease from the second insulating region 32b toward the n⁻-type drift region 21 or p-type base region 22.

The dielectric constant of the FP insulating part 32 may continuously decrease from the FP electrode 14 toward the n⁻-type drift region 21 or p-type base region 22. When the dielectric constant decreases continuously, the inner region of the FP insulating part 32 contacting the FP electrode 14 can be considered to be the first insulating region 32a; and the outer region contacting the n⁻-type drift region 21 or the p-type base region 22 can be considered to be the second insulating region 32b. The thickness of the first insulating region 32a is equal to the thickness of the second insulating region 32b. The dielectric constant at the thickness-direction center of the first insulating region 32a can be considered to be the dielectric constant of the first insulating region 32a. The dielectric constant at the thickness-direction center of the second insulating region 32b can be considered to be the dielectric constant of the second insulating region 32b. For example, it is favorable for the dielectric constant of the FP insulating part 32 to decrease inversely proportionally to the distance from the FP electrode 14. For example, it is favorable for the change rate of the dielectric constant inside the FP insulating part 32 to provide a constant electric field intensity inside the FP insulating part 32.

For example, the dielectric constant of the FP insulating part 32 can be set to continuously decrease from the FP electrode 14 toward the n⁻-type drift region 21 or p-type base region 22 by the FP insulating part 32 including a first material and a second material having a lower dielectric constant than the first material, and by increasing the ratio of the second material to the first material from the FP electrode 14 toward the n⁻-type drift region 21 or p-type base region 22. The first material is, for example, the same as the material of the first insulating region 32a described below. The second material is, for example, the same as the material of the second insulating region 32b described below.

The FP electrode 14 is surrounded with the first insulating region 32a when viewed in plan. The first insulating region 32a is surrounded with the second insulating region 32b when viewed in plan. The second insulating region 32b is surrounded with the p-type base region 22 when viewed in plan. The p-type base region 22 is surrounded with the n⁺-type source region 23 when viewed in plan. The n⁺-type source region 23 is surrounded with the gate insulating part 31 when viewed in plan. The gate electrode 13 is located between the gate insulating parts 31 when viewed in plan.

Multiple FP electrodes 14 are arranged when viewed in plan. In the example, the FP electrodes 14 are arranged in an equilateral triangular configuration when viewed in plan. For example, the FP electrodes 14 may be arranged in a quadrilateral configuration when viewed in plan.

In the example, the shapes of the FP electrode 14 and the FP insulating part 32 are circular when viewed in plan. The shapes of the FP electrode 14 and the FP insulating part 32 when viewed in plan are not limited thereto and may be, for example, polygonal such as triangular, quadrilateral, hexagonal, etc. In the example, the shapes of the gate insulating part 31 and the n⁺-type source region 23 are hexagonal when viewed in plan. The shapes of the gate insulating part 31 and the n⁺-type source region 23 when viewed in plan are not limited thereto and may be, for example, polygonal such as triangular, quadrilateral, etc., or circular.

Examples of the materials of the components of the semiconductor device 100 will now be described.

The drain electrode 11, the source electrode 12, and the gate pad 15 include metals such as aluminum, copper, etc. The gate electrode 13 and the FP electrode 14 include conductive materials such as polysilicon, etc. Impurities may be added to the conductive materials.

The n⁻-type drift region 21, the p-type base region 22, the n⁺-type source region 23, and the n⁺-type drain region 24 include silicon, silicon carbide, gallium nitride, or gallium arsenide as a semiconductor material. When silicon is used as the semiconductor material, arsenic, phosphorus, or antimony can be used as an impurity that forms donors. Boron can be used as an impurity that forms acceptors.

The gate insulating part 31 and the FP insulating part 32 include insulating materials. The gate insulating part 31 includes, for example, silicon oxide (SiO). The first insulating region 32a of the FP insulating part 32 includes, for example, at least one of silicon oxide (SiO), silicon nitride (SiN), silicon oxynitride (SiON), hafnium oxide (HfO), aluminum oxide (AlO), zirconium oxide (ZrO), or lanthanum oxide (LaO). The second insulating region 32b of the FP insulating part 32 includes, for example, at least one of carbon-including silicon oxide (SiOC) or silicon oxide (SiO). It is favorable for the silicon oxide (SiO) included in the second insulating region 32b to be porous. Herein, “porous” refers to a state in which the material has a structure having many micropores that reduce the inherent density and/or dielectric constant of the material. When the first insulating region 32a includes silicon nitride (SiN) or silicon oxynitride (SiON), it is favorable for the second insulating region 32b to include, for example, silicon oxide (SiO). When the first insulating region 32a includes silicon oxide (SiO), it is favorable for the second insulating region 32b to include, for example, carbon-including silicon oxide (SiOC).

Operations of the semiconductor device 100 will now be described.

A voltage that is not less than a threshold is applied to the gate electrode 13 in a state in which a positive voltage with respect to the source electrode 12 is applied to the drain electrode 11. As a result, a channel (an inversion layer) is formed in the p-type base region 22; and the semiconductor device 100 is set to an on-state. Electrons flow from the source electrode 12 toward the drain electrode 11 via the channel. Subsequently, when the voltage that is applied to the gate electrode 13 drops below the threshold, the channel in the p-type base region 22 disappears, and the semiconductor device 100 is set to an off-state.

When the semiconductor device 100 switches to the off-state, the positive voltage with respect to the source electrode 12 that is applied to the drain electrode 11 increases. In other words, the potential difference between the n⁻-type drift region 21 and the FP electrode 14 increases. The potential difference increase causes a depletion layer to spread from the interface between the FP insulating part 32 and the n⁻-type drift region 21 toward the n⁻-type drift region 21. The spreading of the depletion layer can increase the breakdown voltage of the semiconductor device 100. Or, the concentration of the impurity that forms donors in the n⁻-type drift region 21 can be increased to reduce the on-resistance of the semiconductor device 100 while maintaining the breakdown voltage of the semiconductor device 100.

When the FP electrode 14 is included, there are cases where the electric field concentrates at the FP electrode 14 and increases the leakage current. As a result, the reliability of the FP insulating part 32 may degrade.

In contrast, in the semiconductor device 100 according to the embodiment, the FP insulating part 32 that surrounds the FP electrode 14 has a multilayer structure including the first and second insulating regions 32a and 32b; and the dielectric constant of the second insulating region 32b positioned on the outside is less than the dielectric constant of the first insulating region 32a positioned on the inside. As a result, the electric field intensity at the first insulating region 32a can be reduced, and the electric field concentration at the FP electrode 14 can be suppressed. As a result, a leakage current increase can be suppressed, and the reliability of the FP insulating part 32 can be increased.

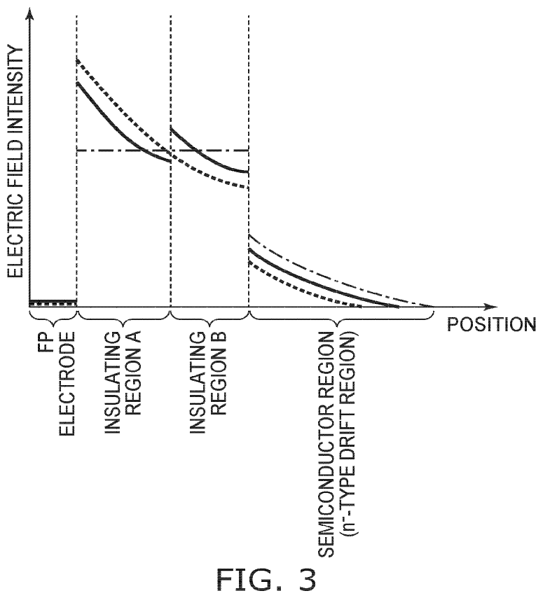

FIG. 3 is a graph illustrating characteristics of semiconductor devices of reference examples.

The horizontal axis of FIG. 3 is the position in the X-Y plane. The vertical axis of FIG. 3 is the electric field intensity.

In FIG. 3, the electric field intensity of a semiconductor device of a reference example 1 is illustrated by a solid line; the electric field intensity of a semiconductor device of a reference example 2 is illustrated by a single dot-dash line; and the electric field intensity of a semiconductor device of a reference example 3 is illustrated by a broken line.

The semiconductor device of the reference example 1 includes the first insulating region 32a at the position of insulating region A of FIG. 3, and includes the second insulating region 32b at the position of insulating region B of FIG. 3. The dielectric constant of the second insulating region 32b is less than the dielectric constant of the first insulating region 32a. The relative dielectric constant of the first insulating region 32a of the semiconductor device of the reference example 1 is 7.5. This value corresponds to the relative dielectric constant when the first insulating region 32a includes silicon nitride (SiN). The relative dielectric constant of the second insulating region 32b of the semiconductor device of the reference example 1 is 3.9. This value corresponds to the relative dielectric constant when the second insulating region 32b includes silicon oxide (SiO).

An electric field intensity E₀ₓ of the insulating region and an electric field intensity E_{Si} of the semiconductor region at a position r are represented by the following formula, wherein ρ is the charge density of the semiconductor region, R_{Si} is the boundary position between the insulating region of the semiconductor region in a polar coordinate system, Rₒₓ is the boundary position between the insulating region and the FP electrode in the polar coordinate system, ε₀ₓ is the dielectric constant of the insulating region, ε_{Si} is the dielectric constant of the semiconductor region, and r is any position in the polar coordinate system. The electric field intensity of the reference example 1 follows this formula.

$${E}_{ox} = \frac{ρ ( {R}_{si}^{2} - {R}_{ox}^{2} )}{2 {ε}_{ox}} \times \frac{1}{r} \qquad [ Formula 1 ]$$

$${E}_{si} = \frac{ρ}{2 {ε}_{si}} \times ( \frac{{R}_{si}^{2}}{r} - r )$$

The semiconductor device of the reference example 2 includes the first insulating region 32a at the position of insulating region A of FIG. 3, and includes the second insulating region 32b at the position of insulating region B of FIG. 3. The dielectric constant in insulating region A and insulating region B continuously decreases from the FP electrode 14 toward the semiconductor region (the n⁻-type drift region 21).

The semiconductor device of the reference example 3 includes the first insulating region 32a at the position of insulating region A and at the position of insulating region B of FIG. 3. That is, the semiconductor device of the reference example 3 does not include the second insulating region 32b. The dielectric constant of the FP insulating part 32 (the first insulating region 32a) of the semiconductor device of the reference example 3 is equal to the dielectric constant of the first insulating region 32a of the semiconductor device of the reference example 1. The thickness of the FP insulating part 32 (the thickness of the first insulating region 32a) of the semiconductor device of the reference example 3 is equal to the thickness of the FP insulating part 32 (the sum of the thickness of the first insulating region 32a and the thickness of the second insulating region 32b) of the semiconductor devices of the reference examples 1 and 2.

As illustrated in FIG. 3 for the semiconductor devices of the reference examples 1 and 2 that include the second insulating region 32b, compared to the semiconductor device of the reference example 3 that does not include the second insulating region 32b, the electric field intensity is greater at the position of insulating region B (that is, the position at which the second insulating region 32b is located), and the electric field intensity is less at the position of insulating region A (that is, the position at which the first insulating region 32a is located) and in the semiconductor region (the n⁻-type drift region 21). These results suggest that the electric field concentration at the FP electrode 14 can be suppressed by including the second insulating region 32b. Also, the semiconductor device of the reference example 2 has a lower electric field intensity change (e.g., the electric field intensity is constant) between the position of insulating region A and the position of insulating region B than the semiconductor device of the reference example 1. This result suggests that the electric field concentration at the FP electrode 14 can be further suppressed by continuously reducing the dielectric constant of the second insulating part 32 from the FP electrode 14 toward the semiconductor region (the n⁻-type drift region 21).

An electric field intensity E₁ in the first insulating region 32a, an electric field intensity E₂ in the second insulating region 32b, and an electric field intensity E₃ in the semiconductor region (the n⁻-type drift region 21) are represented by the following formula, wherein d₁ is the thickness of the first insulating region 32a, d₂ is the thickness of the second insulating region 32b, d₃ is the thickness of the semiconductor region (the n⁻-type drift region 21), ε₁ is the relative dielectric constant of the first insulating region 32a, ε₂ is the relative dielectric constant of the second insulating region 32b, and ε₃ is the relative dielectric constant of the semiconductor region (the n⁻-type drift region 21).

$${E}_{1} = \frac{{ε}_{2} {ε}_{3}}{{e}_{2} {ε}_{3} {d}_{1} + {ε}_{1} {ε}_{3} {d}_{2} + {ε}_{1} {ε}_{2} {d}_{3}} V \qquad [ Formula 2 ]$$

$${E}_{2} = \frac{{ε}_{1} {ε}_{3}}{{ε}_{2} {ε}_{3} {d}_{1} + {ε}_{1} {ε}_{3} {d}_{2} + {ε}_{1} {ε}_{2} {d}_{3}} V$$

$${E}_{3} = \frac{{ε}_{1} {ε}_{2}}{{ε}_{2} {ε}_{3} {d}_{1} + {ε}_{1} {ε}_{3} {d}_{2} + {ε}_{1} {ε}_{2} {d}_{3}} V$$

Thus, the formula above suggests that by setting the FP insulating part 32 that surrounds the FP electrode 14 to have a multilayer structure including the first and second insulating regions 32a and 32b, and by setting the dielectric constant of the second insulating region 32b positioned at the outside to be less than the dielectric constant of the first insulating region 32a positioned at the inside, the electric field intensity in the second insulating region 32b can be increased, and the electric field intensities in the first insulating region 32a and the semiconductor region (the n⁻-type drift region 21) can be reduced.

For example, the FP insulating part 32 and the FP electrode 14 of the semiconductor device 100 according to the embodiment can be formed by the following procedure. First, a hole (a via) is formed in the n⁻-type drift region 21 and the p-type base region 22. Then, the second insulating region 32b is formed inside the hole by CVD (chemical vapor deposition), coating, ALD (atomic layer deposition), thermal oxidation, etc. Then, the first insulating region 32a is formed in the interior of the second insulating region 32b by CVD, coating, ALD, thermal oxidation, etc. Then, the FP electrode 14 is formed in the interior of the first insulating region 32a by CVD, coating, ALD, thermal oxidation, etc. As a result, the FP insulating part 32 that includes the first and second insulating regions 32a and 32b can be formed.

Embodiments may include the following configurations.

### Configuration 1

A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region selectively provided on the second semiconductor region, the third semiconductor region being of the first conductivity type;
a second electrode located on the third semiconductor region, the second electrode being electrically connected with the third semiconductor region;
a third electrode arranged with the second semiconductor region in a second direction and a third direction, the second direction being perpendicular to a first direction, the first direction being from the first electrode toward the second electrode, the third direction being perpendicular to the first direction and crossing the second direction;
a first insulating part located between the second semiconductor region and the third electrode in the second and third directions;
a fourth electrode arranged with the first and second semiconductor regions in the second and third directions; and
a second insulating part located between the first semiconductor region and the fourth electrode and between the second semiconductor region and the fourth electrode in the second and third directions,
the second insulating part including
   a first insulating region surrounding the fourth electrode and contacting the fourth electrode, and
   a second insulating region surrounding the first insulating region and contacting the first insulating region,
a dielectric constant of the second insulating region being less than a dielectric constant of the first insulating region.

### Configuration 2

The device according to configuration 1, wherein
the first insulating region includes at least one of silicon oxide, silicon nitride, silicon oxynitride, hafnium oxide, aluminum oxide, zirconium oxide, or lanthanum oxide.

### Configuration 3

The device according to configuration 1 or 2, wherein
the second insulating region includes at least one of carbon-including silicon oxide or silicon oxide.

### Configuration 4

The device according to any one of configurations 1 to 3, wherein
a thickness of the second insulating region is not less than 0.1 times and not more than 10 times a thickness of the first insulating region.

Thus, according to embodiments, a semiconductor device is provided in which the electric field concentration at the FP electrode can be suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions. Embodiments described above can be implemented in combination with each other.

What is claimed is:

1. A semiconductor device, comprising:
a first electrode;
a first semiconductor region located on the first electrode, the first semiconductor region being of a first conductivity type;
a second semiconductor region located on the first semiconductor region, the second semiconductor region being of a second conductivity type;
a third semiconductor region selectively provided on the second semiconductor region, the third semiconductor region being of the first conductivity type;
a second electrode located on the third semiconductor region, the second electrode being electrically connected with the third semiconductor region;
a third electrode arranged with the second semiconductor region in a second direction and a third direction, the second direction being perpendicular to a first direction, the first direction being from the first electrode toward the second electrode, the third direction being perpendicular to the first direction and crossing the second direction;
a first insulating part located between the second semiconductor region and the third electrode in the second and third directions;
a fourth electrode arranged with the first and second semiconductor regions in the second and third directions; and
a second insulating part located between the first semiconductor region and the fourth electrode and between the second semiconductor region and the fourth electrode in the second and third directions,
the second insulating part including
a first insulating region surrounding the fourth electrode and contacting the fourth electrode, and
a second insulating region surrounding the first insulating region and contacting the first insulating region,
a dielectric constant of the second insulating region being less than a dielectric constant of the first insulating region.

2. The device according to claim 1, wherein
the first insulating region includes at least one of silicon oxide, silicon nitride, silicon oxynitride, hafnium oxide, aluminum oxide, zirconium oxide, or lanthanum oxide.

3. The device according to claim 1, wherein
the second insulating region includes at least one of carbon-including silicon oxide or silicon oxide.

4. The device according to claim 1, wherein
a thickness of the second insulating region is not less than 0.1 times and not more than 10 times a thickness of the first insulating region.
